(19) United States
(12) Patent Application Publication
(10) Pub. No.: US 2007/0007637 A1
(43) Pub. Date: Jan. 11, 2007

(54) Multi-layered substrate assembly with vialess electrical interconnect scheme

(76) Inventor: Valery R. Marinov, Fargo, ND (US)

Correspondence Address: MARSH, FISCHMANN & BREYFOGLE LLP, 3151 SOUTH VAUGHN WAY, SUITE 411, AURORA, CO, 80014, US

(21) Appl. No.: 11/201,682

(22) Filed: Aug. 11, 2005

Related U.S. Application Data
(60) Provisional application No. 60/600,889, filed on Aug. 12, 2004.
(60) Provisional application No. 60/621,756, filed on Oct. 25, 2004.

(51) Int. Cl. H01L 23/02

(52) U.S. Cl. 257/686

(57) ABSTRACT

A multi-layered substrate (42) is disclosed. The substrate (42) includes at least a receptor layer (46) and a bonding layer (64). One or more holes (54) extend completely through the receptor layer (46). A shaped block (10) may be disposed in a given hole (54). When the substrate (42) is compressed, the upper surface (14) of the block (10) and the upper surface (50) of the receptor layer (46) are disposed in coplanar relation, and bonding material (68) from the bonding layer (64) flows into the hole (54) to fill any gap between the receptor layer (46) and the block (10) within the hole (54).

### CROSS-REFERENCE TO RELATED APPLICATIONS

This patent application claims priority under 35 U.S.C. §119(e) to U.S. to Provisional Patent Application Ser. No. 60/600,889, that was filed on Aug. 12, 2004, and that is entitled “METHOD OF INTERCONNECTING ELECTRICALLY SELF-ASSEMBLED MICROSTRUCTURES,” as well as to U.S. Provisional Patent Application Ser. No. 60/621,756, that was filed on Oct. 25, 2004, and that is entitled “MULTI-PIECE SUBSTRATE FOR VIALESS INTERCONNECTS.” The entire disclosure of both of these provisional patent applications is hereby incorporated-by reference in their entirety herein.

### STATEMENTS REGARDING FEDERALLY SPONSORED RESEARCH OR DEVELOPMENT

The U.S. Government has a paid-up license in this invention and the right in limited circumstances to require the patent owner to license others on reasonable terms as provided for by the terms of Grant No. DOD/DMEA/90-3-2-0303 by the Department of Defense.

### FIELD OF THE INVENTION

The present invention generally relates to an electrical interconnect scheme for a substrate assembly that is preferably assembled at least in part using fluidic self assembly and, more particularly, to defining electrical interconnects on an upper surface of a receptor layer that is at least substantially coplanar with an upper surface of blocks that are disposed in holes extending through the receptor layer, thereby alleviating the need for vias to make the electrical interconnection to such blocks.

### BACKGROUND OF THE INVENTION

A process that is referred to as “fluidic self assembly” is described in U.S. Pat. No. 5,545,291, that is entitled “METHOD FOR FABRICATING SELF-ASSEMBLING MICROSTRUCTURES,”, and that issued on Aug. 13, 1996; U.S. Pat. No. 5,904,545, that is entitled “APPARATUS FOR FABRICATING SELF-ASSEMBLING MICROSTRUCTURES,”, and that issued on May 18, 1999; U.S. Pat. No. 6,291,896, that is entitled “FUNCTIONALLY SYMMETRIC INTEGRATED CIRCUIT DIE,” and that issued on Sep. 18, 2001; and U.S. Pat. No. 6,657,289, that is entitled “APPARATUS RELATING TO BLOCK CONFIGURATIONS AND FLUIDIC SELF-ASSEMBLY PROCESSES,” and that issued on Dec. 2, 2003, the disclosures of which are incorporated by reference in their entirety herein. Generally, fluidic self assembly entails forming a plurality of shaped blocks. Each shaped block has at least one electrical component (e.g., an active electrical component, a passive electrical component). These plurality of blocks are disposed in an appropriate fluid that is then directed over a substrate having a plurality of concave recesses formed therein. The plurality of blocks and concave recesses are complimentarily shaped such that one of the blocks may assume a desired position in one of the recesses. Typically a number of the blocks are each deposited in a concave recess on the substrate as the substrate is exposed to the fluid.

Electrical interconnects are formed after a desired number of blocks have been positioned within the concave recesses on the substrate. One way in which this may be done is to form a planarizing layer over the substrate with a plurality of plurality of blocks being disposed in their own substrate recess. This planarizing layer at least assists in retaining the blocks within their respective substrate recess, and further provides a flat surface on which electrical interconnects may be formed. One or more vias must be cut open down through this planarizing layer to an electrical contact or terminal (e.g., a bond or a bonding pad) of the corresponding block. Typically these vias are filled with one type of material. Thereafter, a different material is used to define one or more electrical interconnects (e.g., a line, wire, or trace) on the upper surface of the planarizing layer. One or more masks (e.g., photolithographic) may be used to define the various vias and electrical interconnects. This electrical interconnect scheme thereby requires a number of process steps, which of course adds to both the complexity and cost of the overall fabrication process (e.g., fabrication of one or more masks; deposition of one or more layers of photoresist; alignment of one or more masks; development of the photoresist; etching; stripping of the photoresist). A screen printing processes may also be used to define the electrical interconnects.

### BRIEF SUMMARY OF THE INVENTION

A first aspect of the present invention is embodied by what may be characterized as a substrate assembly. The substrate assembly includes a receptor layer, a first block, a bonding layer, and a first electrical interconnect. The receptor layer includes at least one hole (hereafter a first hole) that extends between its oppositely disposed first and second surfaces. The first block includes a first electrical terminal and is disposed within the first hole of the receptor layer. A bonding material interfaces with the second surface of the receptor layer, while a first electrical interconnect extends along the oppositely disposed first surface of the receptor layer and to the first electrical terminal of the first block.

Various refinements exist of the features noted in relation to the first aspect of the present invention. Further features may also be incorporated in the first aspect of the present invention as well. These refinements and additional features may exist individually or in any combination. The receptor layer may include any appropriate number of first holes. Each first hole may be of the same size, shape, and configuration, although such need not be the case (e.g., a first group of first holes may be of one size, shape, and/or configuration, while another group of first holes may be of a different size, shape, and/or configuration). A separate first block may be disposed in each of multiple first holes through the receptor layer, such that the substrate assembly may include multiple first blocks, each being disposed in their own first hole through the receptor layer. Although each first block could be of the same size, shape, and configuration, such need not be the case. Each first block may be complementarily-shaped so as to be disposed within a first hole in a particular orientation, although such need not be the case.

The receptor layer may be of any appropriate configuration. In one embodiment, the receptor layer is a flexible structure. In another embodiment, the receptor layer is a rigid structure. The receptor layer also may be formed of any appropriate material or combination of materials, but will typically be a dielectric as the first electrical interconnect is disposed directly on its first surface. The first electrical interconnect may be of any appropriate type, size, shape, and configuration (e.g., a line, trace), and the substrate assembly may include any appropriate number of first electrical interconnects and in any appropriate arrangement.

Each first block may provide any appropriate functionality, but will typically include at least one electrical component. Herein, “electrical component” means any component that sends or transmits an electrical signal, that receives an electrical signal, or both, including without limitation a single circuit element. Any number of electrical components may be included on each first block and in any appropriate arrangement. The first block may also include any appropriate number of first electrical terminals.

The first electrical terminal associated with the first block may be located on a first surface of the first block. This first surface of the first block may be at least substantially coplanar with the first surface of the receptor layer on which the first electrical interconnect is formed. The first block may include a second surface that is disposed directly opposite of its first surface. The bonding material may interface with the entirety of second surface of the first block. The first block also may be characterized as being seated within the bonding material. For instance, the first block may create a depression in the bonding material during assembly. Another characterization is that the first block has first and second ends, where the first end has the first electrical terminal and is disposed at least substantially coplanar with the first surface of the receptor layer on which the first electrical interconnect is disposed, and where at least the second end of the first block is embedded within the bonding material.

An annular first sidewall of the receptor layer may define the first hole, and the first block may include an annular sidewall. At least part of the sidewall of the first block may be spaced from the first sidewall that defines the first hole through the receptor layer. Preferably, any gap between the first sidewall of the receptor layer and the sidewall of the first block within the first hole is occupied by bonding material. One embodiment has the entirety of the first block being spaced from the annular first sidewall that defines the first hole through the receptor layer. In this case, the entirety of the space between the first block and the annular first sidewall is preferably occupied by bonding material. Another embodiment has an annular portion of the first block (e.g., an uppermost portion of a sidewall of the first block) being in contact with part of the first sidewall that defines the first hole through the receptor layer (hereafter a “zero clearance fit”), with the remainder of the first block being spaced from this first sidewall. That is, the zero clearance relationship need not exist between all corresponding portions of the first sidewall and the perimeter of the first block (e.g., the entire first sidewall that defines the first hole through the receptor layer need not be contacted by the first block; the entire thickness of the first block need not contact the first sidewall that defines the first hole through the receptor layer). In this case as well, the entirety of any space between the annular first sidewall and the remainder of the first block within the first hole is preferably occupied by bonding material. Preferably, any gap between the receptor layer and all portions of the first block within the first hole are occupied by bonding material, including where this gap exists at the first surface of the receptor layer on which the first electrical interconnect is disposed. In this case, the bonding material that is disposed within this gap is also preferably coplanar with the first surface of the receptor layer on which the first electrical interconnect is disposed. This allows the first electrical interconnect to cross this “filled” gap to contact the first electrical terminal on the first block.

Any appropriate type of material or combination of materials may define the bonding material. The bonding material may also be in any appropriate form, including a solid, liquid, or paste. It may be desirable for the bonding material to be sufficiently viscous in one or more instances (e.g., prior to and/or during compression of the substrate assembly), and which may require a heat treatment of the bonding material. One embodiment has the bonding material in the form of an appropriate adhesive impregnated carrier (e.g., cloth, mesh, paper). This adhesive may be used to fill any gap between the receptor layer and the first block within the first hole, and further may secure the position of the first block relative to the receptor layer.

The substrate assembly may include any appropriate number of layers. In one embodiment, a backup layer is provided such that the bonding material is disposed or retained between the backup layer and the receptor layer. The backup layer may be of any appropriate material or combination of materials, and may be of any appropriate size, shape, and configuration. Similarly, a release layer or film may be removably disposed on the first surface of the receptor layer and on a corresponding surface of the first block. This release film may be used when placing the substrate assembly in compression to force bonding material into any gap between the receptor layer and the first block after it has been properly positioned within the first hole. Although the first electrical interconnect will typically be defined or formed after the release film has been removed, such need not always be the case. Another option would be to include such a release film on a portion of a structure that contacts the receptor layer in order to compress the substrate assembly in a manner that will be discussed in more detail below. A release film could be disposed on both the receptor layer and the above-noted structure. Yet another option would be to spray a release material on the receptor layer and/or the above-noted structure.

In a preferred embodiment, an upper surface of the receptor layer and an upper surface of the first block are at least substantially coplanar. There may or may not be a zero clearance fit between the receptor layer and the first block when positioned within the first hole. However, at least part of a first sidewall that defines the first hole through the receptor layer and a sidewall of the first block within the first hole are separated by a space, and bonding material occupies at least substantially all of this space. An electrical interconnect extending across the upper surface of the receptor layer may cross and be supported by the upper end of bonding material within the first hole prior to reaching the upper surface of the first block if there is a gap between an upper edge of the first block and an upper edge of the first hole through the receptor layer. Having the upper surface of the receptor layer, the upper surface of the first block, and the upper end of the bonding material within the first hole being coplanar allows at least substantially the entirety of the electrical interconnect to be supported and remain at an at least substantially constant elevation. However, a zero clearance relationship could exist between the receptor layer and the upper edge of the first block when positioned within the first hole such that the electrical interconnect need not “cross” a bonding material filled gap to progress from the upper surface of the receptor layer to the upper surface of the first block.

A second aspect of the present invention is embodied by a method for making a substrate assembly. The substrate assembly includes a receptor layer having a first hole. A first block is directed into the first hole from a first side of the receptor layer. A bonding layer is disposed on a second side of the receptor layer that is opposite the first side. That is, the first block is installed into the first hole from the side of the receptor layer that is opposite that which interfaces with the bonding layer. The receptor layer and bonding layer may be collectively referred to as a substrate. This substrate is compressed and a bonding material from the bonding layer is directed into a space between the first block and an annular sidewall of the receptor layer that defines the first hole in which the first block is positioned.

Various refinements exist of the features noted in relation to the second aspect of the present invention. Further features may also be incorporated in the second aspect of the present invention as well. These refinements and additional features may exist individually or in any combination. For instance, the various features discussed above in relation to the first aspect may be utilized by or incorporated into this second aspect as well, individually or in any appropriate combination.

The first block may be directed into the first hole of the receptor layer in any appropriate manner (e.g., using a “pick and place” technology; robotically). More preferably this is done using what may be characterized as fluidic self assembly. In this case the first block is disposed within a fluid that is put into contact with at least the first side of the receptor layer such that the first block in effect may be carried by the fluid and allowed to “settle” into the first hole of the receptor layer. Stated another way, there may be a flow of sorts at least generally along a first surface of the receptor layer on its first side that allows the first block to be positioned within the first hole of the receptor layer. This “flow” may be of the first block through the fluid, or a flow of the fluid with the first block as well. Typically, a plurality of blocks will be disposed in a fluid to form a slurry, and at least the first side of the receptor layer will be exposed to this slurry. This of course encompasses having the receptor layer be totally submerged in the slurry. At least certain of these blocks and the first hole may be complementarily-shaped—that is, such that the first hole is shaped to accommodate receipt of one of these blocks and typically within a certain orientation within the first hole. It should be appreciated that typically the receptor layer will include a plurality of similarly-shaped first holes, each of which may then receive a single, complimentarily-shaped block in the noted manner.

In one embodiment where there is a zero clearance fit between the first block and the receptor layer when the first block is positioned within the first hole, the first block is positioned within the first hole from the first side of the receptor layer before the bonding layer is disposed on the second, opposite side of the receptor layer. Fluidic self assembly could thereby be used to position the first block within the first hole prior to assembling the bonding layer and receptor layer (e.g., the bonding layer could be attached to or formed on the second side of the receptor layer after fluidic self assembly has been completed). Another option would be for the bonding layer to be disposed on the second side of the receptor layer prior to positioning the first block within the first hole of the receptor layer. Fluidic self assembly could thereby be used to position the first block within the first hole after the bonding layer has already been formed on or attached to the second side of the receptor layer. The substrate could include one or more additional layers, including at the time of fluidic self assembly (e.g., a backup layer that “sandwiches” the bonding layer between the backup layer and the receptor layer).

The first block may be the same thickness as or thinner than the receptor layer. That is, a first surface of the first block initially may be at least substantially coplanar with or recessed relative to a first surface of the receptor layer on the first side of the receptor layer. Compression of the substrate may thereafter dispose the first surface of the receptor layer in at least substantially coplanar relation with the first surface of the first block. Generally, the bonding material of the bonding layer may “push” the first block within the first hole (toward the first side) such that its first surface is at least substantially coplanar with the first surface of the receptor layer. Compression of the substrate may also direct bonding material of the bonding layer into any gap between the receptor layer and the first block within the first hole. Preferably, any gap between the receptor layer and the first block within the first hole is at least substantially “filled” by bonding material of the bonding layer being forced into this gap by the compression of the substrate. This then provides an at least substantially planar and continuous surface along which electrical interconnects may extend (and also holds the first block in place). That is, one or more electrical interconnects may extend along the first surface of the receptor layer and onto the first surface of a first blocks without being unsupported across any gap between an upper edge of the first hole and an upper edge of the first block because of the existence of bonding material in this gap.

In the case where the receptor layer is thicker than the first block, the first hole may be “bigger around” or larger than any portion of the first block positioned therein (e.g., there is no zero clearance fit between the receptor layer and the first block in this instance). For instance, the maximum effective size of the first block may be less than the maximum effective size of the first hole at the first surface of the receptor layer. Stated another way, the perimeter of the first hole at a first surface of the receptor layer on its first side may be larger than the maximum perimeter of the first surface of the first block. Therefore, a gap will exist between at least part of the receptor layer and the first block when their respective first surfaces are disposed in at least substantially coplanar relation (including having an annular gap between the receptor layer and the first block). Again, preferably this gap is “filled” by bonding material of the bonding layer from the compression of the substrate.

The first block also may be thicker than the receptor layer. In this case a first surface of the receptor layer on its first side initially may be recessed relative to a first surface of the first block (e.g., the first block may initially “protrude” from the first surface of the receptor layer). Compression of the substrate may thereafter dispose the first surface of the receptor layer in at least substantially coplanar relation with the first surface of the first block. Generally, the first block may be “pressed down” into the bonding layer. This may form a depression within the bonding layer. Compression of the substrate may also direct bonding material of the bonding layer into any gap between the receptor layer and the first block within the first hole. Preferably, any gap between the receptor layer and the first block within the first hole is “filled” by bonding material of the bonding layer being forced into this gap by the compression of the substrate. This then provides a substantially planar and continuous surface along which electrical interconnects may extend. That is, one or more electrical interconnects may extend along the first surface of the receptor layer and onto the first surface of a first block without being unsupported across any gap between an upper edge of the first hole and an upper edge of the first block because of the existence of bonding material in this gap.

In the case where the receptor layer is thinner than the first block, the first hole again may be “bigger around” or larger than the first block positioned therein (e.g., there is no zero clearance fit between the receptor layer and the first block in this instance). For instance, the maximum effective size of the first block may be less than the maximum effective size of the first hole at the first side of the receptor layer. Stated another way, the perimeter of the first hole at a first surface of the receptor layer on its first side may be larger than the maximum perimeter of the first block. Therefore, a gap may exist between at least part of the receptor layer and the first block when disposed in at least substantially coplanar relation on the first side of the receptor layer (including having an annular gap between the receptor layer and the first block within the first hole). Again, preferably this gap is “filled” by bonding material of the bonding layer from the compression of the substrate.

In the case where the receptor layer is thinner than the first block, the first hole also may be the same size as or “smaller” than the first block positioned therein in at least some respect such that there is a zero clearance fit between the perimeter of the first block (at least at its upper edge) and the perimeter of the first hole in the receptor layer (at least at its upper edge). Preferably, no appreciable forces are required to dispose the first block within the first hole in the receptor layer to realize this zero clearance fit, although a press or interference fit relationship could exist between the first block and the receptor layer if warranted. In relation to the noted zero clearance fit, the maximum effective size of the first block may be the same as the maximum effective size of the first hole at the first side of the receptor layer, or the maximum effective size of the first block may be greater than the maximum effective size of the first hole at the first side of the receptor layer. Stated another way, the perimeter of the first hole at a first surface of the receptor layer on its first side may be the same as or smaller than the maximum perimeter of the first block. Therefore, an annular first portion of the first block may be in contact with the receptor layer at its first side prior to the substrate being compressed or after the substrate has been compressed. The result of the subsequent compression of the substrate is subject to a number of characterizations in this situation. One is that the compression may at least slightly deform the receptor layer (e.g., by enlarging at least part of the first hole somewhat). Another is that the compression provides a zero clearance fit between an annular first portion of the first block and a corresponding portion of the sidewall of the receptor layer that defines the first hole. The remainder of the sidewall of the receptor layer that defines the first hole may remain spaced from the first block within the first hole. Again, preferably bonding material of the bonding layer is forced into this gap by the compression of the substrate.

Any appropriate way of placing the substrate in compression may be utilized. It may be desirable to provide a release layer over the receptor layer and the first block prior to placing the substrate in compression. Once the substrate has been compressed, the release layer may be removed. Heat may be applied prior to and/or during the compression as well if desired/required for the bonding material of the bonding layer, including that which was directed into the first hole. Any appropriate way of heat treating the bonding material of the bonding layer may be undertaken. One or more materials for the bonding layer may be appropriate and may not require any heat treatment at all. In any case, the bonding material appropriately “fixes” the first block within the first hole of the receptor layer. For at least certain bonding materials, it may be desired to “capture” or sandwich the bonding layer between the receptor layer and a backup layer. This backup layer could then be part of the substrate that is compressed in accordance with the foregoing.

A third aspect of the present invention is embodied by a method for making a substrate assembly. The substrate assembly includes a receptor layer having first and second oppositely disposed surfaces, as well as a first hole that extends between these first and second surfaces. A first block is at least partially positioned in the first hole of the receptor layer. This first block includes a first electrical terminal on its first surface. A bonding layer is disposed on the second surface of the receptor layer. The receptor layer and bonding layer may be collectively referred to as a substrate. The substrate is compressed to dispose the first surface of the first block (having the first electrical terminal) at least substantially coplanar with the first surface of the receptor layer. A first electrical interconnect is formed on the first surface of the receptor layer and on the first surface of the first block, that again are disposed in at least substantially coplanar relation.

Various refinements exist of the features noted in relation to the third aspect of the present invention. Further features may also be incorporated in the third aspect of the present invention as well. These refinements and additional features may exist individually or in any combination. For instance, the various features discussed above in relation to the first aspect may be utilized by or incorporated into this third aspect as well, individually or in any appropriate combination.

The first block may be directed into the first hole of the receptor layer in any appropriate manner (e.g., using a “pick and place” technology; robotically). More preferably this is done using what may be characterized as fluidic self assembly. In this case the first block is disposed within a fluid that is put into contact with at least the first surface of the receptor layer such that the first block in effect may be carried by the fluid and allowed to “settle” into the first hole of the receptor layer. Stated another way, there may be a flow of sorts at least generally along the first surface of the receptor layer that allows the first block to be positioned within the first hole of the receptor layer. This “flow” may be of the first block through the fluid, or a flow of the fluid with the first block as well. Typically, a plurality of blocks will be disposed in a fluid to form a slurry, and at least the first surface of the receptor layer will be exposed to this slurry. This of course encompasses having the receptor layer be totally submerged in the slurry. At least certain of these blocks and the first hole may be complementarily-shaped—that is, such that the first hole is shaped to accommodate receipt of one of these blocks and typically within a certain orientation within the first hole. It should be appreciated that typically the receptor layer will include a plurality of similarly-shaped first holes, each of which may then receive a single, complimentarily-shaped block in the noted manner.

In one embodiment where there is a zero clearance fit between the first block and the receptor layer when the first block is positioned within the first hole, the first block is positioned within the first hole of the receptor layer before the bonding layer is disposed on the second surface of the receptor layer. Fluidic self assembly could thereby be used to position the first block within the first hole prior to assembling the bonding layer and receptor layer (e.g., the bonding layer could be attached to or formed on the second surface of the receptor layer after fluidic self assembly has been completed). Another option would be for the bonding layer to be disposed on the second surface of the receptor layer prior to positioning the first block within the first hole of the receptor layer. Fluidic self assembly could thereby be used to position the first block within the first hole after the bonding layer has already been formed on or attached to the second surface of the receptor layer. The substrate could include one or more additional layers, including at the time of fluidic self assembly (e.g., a backup layer that “sandwiches” the bonding layer between the backup layer and the receptor layer).

The first block may be the same thickness as or thinner than the receptor layer. In this case, the first surface of the first block initially may be at least substantially coplanar with or recessed relative to the first surface of the receptor layer. Compression of the substrate may thereafter dispose the first surface of the receptor layer in at least substantially coplanar relation with the first surface of the first block. Generally, the bonding material of the bonding layer may “push” the first block within the first hole (in the direction of the first surface of the receptor layer) such that its first surface is at least substantially coplanar with the first surface of the receptor layer. Compression of the substrate may also direct bonding material of the bonding layer into any gap between the receptor layer and the first block. Preferably, any gap between the receptor layer and the first block within the first hole is at least substantially “filled” by bonding material of the bonding layer being forced into this gap by the compression of the substrate. This then provides a substantially planar and continuous surface along which electrical interconnects may extend (and also holds the first block in place). That is, one or more electrical interconnects may extend along the first surface of the receptor layer and onto the first surface of a first block without being unsupported across any gap between an upper edge of the first hole and an upper edge of the first block because of the existence of bonding material in this gap.

In the case where the receptor layer is thicker than the first block, the first hole may be “bigger around” or larger than the first block positioned therein (e.g., there is no zero clearance fit between the receptor layer and the first block in this instance). For instance, the maximum effective size of the first block may be less than the maximum effective size of the first hole at the first surface of the receptor layer. Stated another way, the perimeter of the first hole at the first surface of the receptor layer may be larger than the maximum perimeter of the first block. Therefore, a gap will exist between at least part of the receptor layer and the first block when their respective surfaces are disposed in at least substantially coplanar relation (including having an annular gap between the receptor layer and the first block). Again, preferably this gap is “filled” by bonding material of the bonding layer from the compression of the substrate.

The first block also may be thicker than the receptor layer. In this case the first surface of the receptor layer initially may be recessed relative to the first surface of the first block (e.g., the first block may initially “protrude” beyond the first surface of the receptor layer). Compression of the substrate may thereafter dispose the first surface of the receptor layer in at least substantially coplanar relation with the first surface of the first block. Generally, the first block may be “pressed down” into the bonding layer. This may form a depression within the bonding layer. Compression of the substrate may also direct bonding material of the bonding layer into any gap between the receptor layer and the first block within the first hole. Preferably, any gap between the receptor layer and the first block within the first hole is “filled” by bonding material of the bonding layer being forced into this gap by the compression of the substrate. This then provides a substantially planar and continuous surface along which electrical interconnects may extend. That is, one or more electrical interconnects may extend along the first surface of the receptor layer and onto the first surface of a first block without being unsupported across any gap between an upper edge of the first hole and an upper edge of the first block because of the existence of bonding material in this gap.

In the case where the receptor layer is thinner than the first block, the first hole also may be “bigger around” or larger than the first block positioned therein (e.g., there is no zero clearance fit between the receptor layer and the first lock in this instance). For instance, the maximum effective size of the first block may be less than the maximum effective size of the first hole at the first surface of the receptor layer. Stated another way, the perimeter of the first hole at the first surface of the receptor layer may be larger than the maximum perimeter of the first block. Therefore, a gap may exist between at least part of the receptor layer and the first block when their respective first surfaces are disposed in at least substantially coplanar relation (including having an annular gap between the receptor layer and the first block within the first hole). Again, preferably this gap is “filled” by bonding material of the bonding layer from the compression of the substrate.

In the case where the receptor layer is thinner than the first block, the first hole also may be the same size as or “smaller” than the first block in at least some respect such that there is a zero clearance fit between the perimeter of the first block (at least at its upper edge) and the perimeter of the first hole in the receptor layer (at least at its upper edge). Preferably, no appreciable forces are required to dispose the first block within the first hole in the receptor layer to realize this zero clearance fit, although a press or interference fit relationship could exist between the first block and the receptor layer if warranted. In relation to the noted zero clearance fit, the maximum effective size of the first block may be the same as the maximum effective size of the first hole at the first side of the receptor layer, or the maximum effective size of the first block may be greater than the maximum effective size of the first hole at the first surface of the receptor layer. Stated another way, the perimeter of the first hole at a first surface of the receptor layer may be the same as or smaller than the maximum perimeter of the first block. Therefore, an annular first portion of the first block may be in contact with the receptor layer at least at the intersection of the first hole with the first surface of the receptor layer and prior to the substrate being compressed or after the substrate has been compressed. The result of the subsequent compression of the substrate is subject to a number of characterizations in this situation. One is that the compression may at least slightly deform the receptor layer (e.g., by enlarging at least part of the first hole somewhat). Another is that the compression provides a zero clearance fit between an annular first portion of the first block and a corresponding portion of the sidewall of the receptor layer that defines the first hole. The remainder of the sidewall of the receptor layer may remain spaced from the first block within the first hole that defines the first hole. Again, preferably bonding material of the bonding layer is forced into this gap by the compression of the substrate.

Any appropriate way of placing the substrate in compression may be utilized. It may be desirable to provide a release layer over the receptor layer and the first block prior to placing the substrate in compression. Once the substrate has been compressed, the release layer may be removed. Heat may be applied prior to and/or during the compression as well if desired/required for curing the bonding material of the bonding layer. Any appropriate way of heat treating the bonding material of the bonding layer may be undertaken. One or more materials for the bonding layer may be appropriate and may not require any heat treatment at all. In any case, the bonding material appropriately “fixes” the first block within the first hole of the receptor layer. For at least certain bonding materials, it may be desired to “capture” or sandwich the bonding material between the receptor layer and a backup layer. This backup layer could then be part of the substrate that is compressed in accordance with the foregoing.

Each of the various features discussed in relation to any of the first, second, and third aspects may be used in any of the other aspects of the invention described herein, individually or in any combination.

### BRIEF DESCRIPTION OF THE SEVERAL VIEWS OF THE DRAWING

FIG. 1 is a top view of one embodiment of a block having at least one electrical component that may be deposited within a recess on a substrate.

FIG. 2A is a cutaway side view of one embodiment of a substrate assembly where a plurality of shaped blocks of the type presented in FIG. 1 have been positioned within recesses on a substrate.

FIG. 2B is a schematic that illustrates principles of fluidic self assembly that may be used for positioning the blocks within the substrate recesses for the substrate assembly of FIG. 2A.

FIG. 3A is a cross-sectional view of one embodiment of a multi-layered substrate that may be used in place of the substrate of FIGS. 2A-B.

FIG. 3B is a cross-sectional view of another embodiment of a multi-layered substrate that may be used in place of the substrate of FIGS. 2A-B.

FIG. 3C is a cross-sectional view of another embodiment of a multi-layered substrate that may be used in place of the substrate of FIGS. 2A-B.

FIG. 4 is a schematic representation of one embodiment for assembling any of the multi-layered substrates of FIG. 3A-C.

FIG. 5A is a cross-sectional view of a substrate assembly that uses the substrate of FIG. 3A, and having a block positioned within one of the holes through the receptor layer of the substrate, where the block is sized so that its upper surface is recessed relative to an upper surface of the receptor layer and further such that there is no interference fit between the receptor layer and block.

FIG. 5B is the cross-sectional view of the substrate assembly of FIG. 5A after being compressed to dispose the upper surface of the block and the upper surface of the receptor layer of the substrate in at least substantially coplanar relation.

FIG. 6A is a cross-sectional view of a substrate assembly that uses the substrate of FIG. 3A, and having a block positioned within one of the holes through the receptor layer of the substrate, where the block is sized so that its upper surface protrudes beyond an upper surface of a receptor layer of the substrate and further such that there is no interference fit between the receptor layer and block.

FIG. 6B is the cross-sectional view of the substrate assembly of FIG. 6A after being compressed to dispose the upper surface of the block and the upper surface of the receptor layer of the substrate in at least substantially coplanar relation.

FIG. 7A is a cross-sectional view of a substrate assembly that uses the substrate of FIG. 3A, and having a block positioned within one of the holes through the receptor layer of the substrate, where the block is sized so that its upper surface protrudes beyond an upper surface of a receptor layer of the substrate and further such that the block contacts the receptor layer at least at the intersection of the through hole with the upper surface of the receptor layer.

FIG. 7B is the cross-sectional view of the substrate assembly of FIG. 7A after being compressed to dispose the upper surface of the block and the upper surface of the receptor layer of the substrate in at least substantially coplanar relation, and further to provide a press or interference fit between the receptor layer and block.

FIG. 8A is a top or plan view of an electrical interconnect that may be formed on one arrangement of the substrate assembly of both FIGS. 5B and 6B.

FIG. 8B is a top or plan view of an electrical interconnect that may be formed on another arrangement of the substrate assembly of both FIGS. 5B and 6B.

FIG. 8C is a top or plan view of an electrical interconnect formed on the substrate assembly of FIG. 7B.

### DETAILED DESCRIPTION OF THE INVENTION

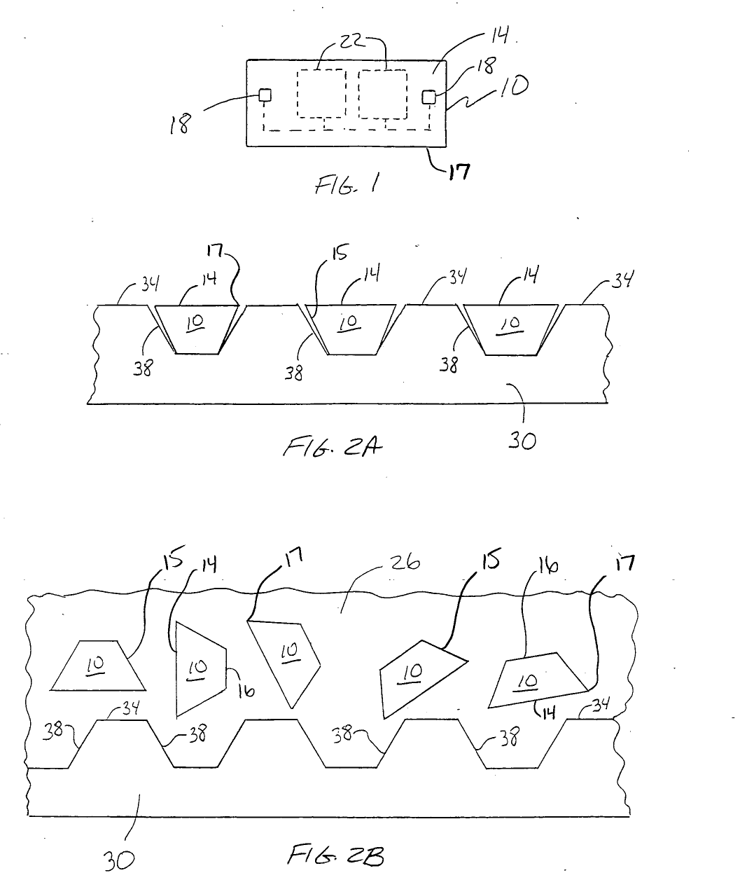

The present invention will now be described in relation to the accompanying drawings which at least assist in illustrating its various pertinent features. One end of one embodiment of a shaped block is illustrated in FIG. 1 and is identified by reference numeral 10. The block 10 may be of any appropriate size, shape, and/or configuration, may be formed from any material or combination of materials, and further may provide any appropriate functionality or combination of functionalities. Generally, the block 10 is positioned in an at least generally complimentarily-shaped receptor site, receptacle, or concave recess 38 that exists on a substrate 30 and in the manner illustrated in FIG. 2A. The gap between the blocks 10 and the substrate 30 when the block 10 is disposed within a recess 38 also may be smaller or larger than that illustrated in FIG. 2A. An upper surface 14 of the block 10 may be at least generally coplanar with an upper surface 34 of the substrate 30, although such will not typically be the case, as the blocks 10 are typically somewhat “cocked” within the recesses 38. Features may be incorporated such that a block 10 can only be positioned within a recess 38 in a single orientation (e.g., by using one or more self-aligning or registration features).

The substrate 30 may be of any size, shape, and/or configuration, and further may be formed from any appropriate material or combination of materials. Once again and as illustrated in FIG. 2A, the substrate 30 includes a plurality of concave recesses 38 on its upper surface 34. Any appropriate number of recesses 38 may be utilized by the substrate 30. The various recesses 38 may be arranged in any appropriate manner, and further may be formed in any appropriate manner. The substrate 30 may also include any number of other components and in any appropriate arrangement.

The block 10 includes an upper surface 14 as noted and an oppositely disposed lower surface 16. An annular sidewall 15 extends between the upper surface 14 and lower surface 16, and may be of any appropriate configuration and disposed in any appropriate orientation relative to the surfaces 14, 16. “Annular” means that the sidewall 15 extends a full 360 degrees about a reference axis of the block 10 that extends between the surfaces 14, 16, and by no means limits the configuration of the sidewall 15 to being cylindrical. The intersection of the sidewall 15 with the upper surface 14 defines an upper edge 17.

The block 10 includes at least one electrical contact, bond/bonding pad, or electrical terminal 18 for providing an electrical signal to the block 10 and/or retrieving an electrical signal from the block 10. Typically this electrical terminal 18 will be on the upper surface 14 of the block 10. Any number of terminals 18 may be utilized by the block 10, each terminal 18 may be of any appropriate size, shape, and/or configuration, and each terminal 18 may be disposed at any appropriate location on the block 10. The block 10 further includes at least one electrical component 22. Herein “electrical component 22” means any component that sends or transmits an electrical signal, that receives an electrical signal, or both. Representative electrical components 22 includes without limitation active elements (capable of delivering power to some external device, such as dependent and independent voltage and current sources), passive elements (e.g., resistors, capacitor, inductors), integrated circuits, semiconductor devices, antennas, power sources, electromechanical devices, sensors, transducers, or the like.

Any number of electrical components 22 may be used by a given block 10, and furthermore the electrical components 22 may be disposed in any appropriate arrangement, may be electrically interconnected in any appropriate manner, and may provide any appropriate function or combination of functions. Each electrical component 22 is electrically interconnected (directly or indirectly) with one or more of the terminals 18 in any appropriate manner. Any appropriate number of terminals 18 and electrical components 22 may be used by the block 10, and the various terminals 18 and electrical components 22 may be disposed in any appropriate arrangement. A plurality of the blocks 10 will typically be simultaneously fabricated using an appropriate substrate (not shown)—ultimately to define a plurality of separate blocks 10 for positioning with recesses 38 on the substrate 30.

A preferred approach for positioning blocks 10 within recesses 38 formed on the substrate 30 may be referred to as fluidic self assembly. The fundamental principles of fluidic self assembly are illustrated in FIG. 2B. Generally, a plurality of blocks 10 are disposed in an appropriate fluid 26 (e.g., such that the blocks 10 are suspended in the fluid 26; the fluid 26 typically being a liquid) to define a slurry of sorts that is put into contact with at least the upper surface 34 of the substrate 30. There is relative movement between at least the various blocks 10 and the substrate 30 such that blocks 10 are able to settle and be retained within a recess 38 on the substrate 30. This may be accomplished by directing a flow of the fluid 26 (with the blocks 10 therein) over the upper surface 34 of the substrate 30. Another appropriate approach would be to dispose the substrate 30 within a reservoir of fluid 26 at an angle such that blocks 10 introduced into the fluid 26 would progress along the upper surface 34 of the substrate 30 and be deposited in the recesses 38 (e.g., U.S. Pat. No. 5,904,545 noted above).

After a desired number of substrate recesses 38 have received a block 10 in accordance with the general technique illustrated in FIG. 2A, the substrate 30 is removed from the fluid 26. One or more processing steps thereafter may be undertaken to secure each block 10 within its corresponding recess 38. For instance, an overlying planarizing layer may be formed over the upper surface 34 of the substrate 30. This not only provides the above-noted function, but also provides a desired surface (flat) for wiring. In this regard, electrical interconnects will typically be formed on the planarizing layer for one or more of the blocks 10 disposed within the substrate recess 38, as well as for one or more other components that are associated with the substrate 30. These “other components” will typically be mounted on or fabricated using the substrate 30 prior to assembling the blocks 10 within the substrate recesses 38, although such need not always be the case. It also may be such that one or more components are mounted on or fabricated using the planarizing layer. Electrical interconnects may also be formed on the upper surface of the planarizing layer for any of these components as well.

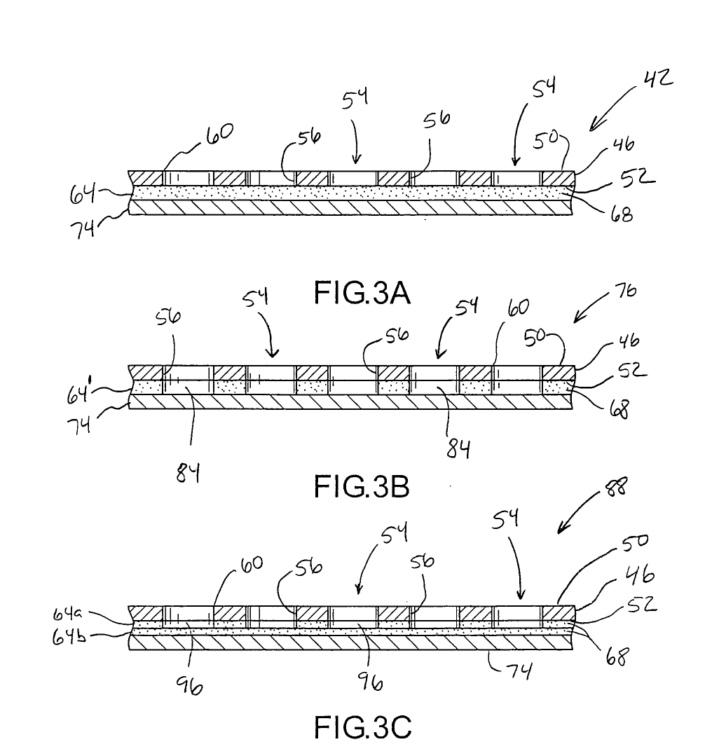

The above-noted in planarizing layer obviously requires a number of processing steps which of course adds to the overall cost of the fabrication process. These steps include the formation of the planarizing layer, and the formation of vias or holes that extend down through the planarizing layer to the underlying block 10 or other component so as to be able to establish electrical communication therewith. Various embodiments of a multi-layered or composite substrate that each alleviate the need for this planarizing layer, and thereby all related processing steps, are illustrated in FIGS. 3A-C.

The substrate 42 of FIG. 3A includes a first or receptor layer 46, a second or bonding layer 64 of an appropriate bonding material 68, and a third or backup layer 74. Any number of layers may be used for the substrate 42, although the receptor layer 46 and bonding layer 64 are required in all instances (i.e., the backup layer 74 may be optional in at least certain situations). Generally, each of these layers 46, 64, and 74 may be of any size, shape, and configuration, may be formed from any appropriate material or combination of materials, and may be of any appropriate thickness. Any appropriate way of assembling the various layers of the substrate 42 may be utilized as well. For instance, the various layers of the substrate 42 could be simultaneously joined, or multiple layers could be separately joined, and then joined to another layer or layers of the substrate 42.

The receptor layer 46 of the substrate 42 includes an upper surface 50 and an oppositely disposed lower surface 52. Both the upper surface 50 and the lower surface 52 will typically be at least substantially flat or planar. The receptor layer 46 may be formed from any appropriate material or combination of materials. In one embodiment, the receptor layer 46 is formed from a dielectric material. Representative materials for the receptor layer 46 include without limitation polyimide, polyester, and polyethylene napthalate. The receptor layer 46 also may be flexible, rigid, or otherwise.

A plurality of holes 54 extend from the upper surface 50 to the lower surface 52 of the receptor layer 46, and thereby pass through the entire thickness or vertical extent of the receptor layer 46. An annular sidewall 56 defines a perimeter of each hole 54. The sidewall 56 of each hole 54 may be of any appropriate configuration and disposed in any appropriate orientation relative to the upper surface 50 and lower surface 52 of the receptor layer 46. The intersection of a given sidewall 56 with the upper surface 50 defines an upper edge 60 of the hole 54.

Any number of holes 54 may be used by the receptor layer 46, and the holes 54 may be disposed in any appropriate arrangement. Moreover, the holes 54 may be of appropriate any size, shape, and configuration. In one embodiment, all holes 54 are of the same size, shape, and configuration. In another embodiment, there are at least two different groups of holes 54, where any hole 54 in one group differs in at least some respect from a hole 54 in a different group. In the illustrated embodiment, the sidewall 56 of each hole 54 is perpendicular to the upper surface 50 and lower surface 52 of the receptor layer 46. However and in accordance with the foregoing, the sidewall 56 of each hole 54 could be disposed at a different angle relative to the upper surface 50 and lower surface 52 of the receptor layer 46, such as an inclined orientation as illustrated in relation to the concave recesses 38 in FIG. 2A.

The holes 54 may be formed through the receptor layer 46 in any appropriate manner. In one embodiment the holes 54 are formed by laser cutting or drilling. Other appropriate techniques- for forming the holes 54 include without limitation punching, electron discharge machining, and water jet cutting. Typically, the bonding layer 64 will be positioned against and secured to the lower surface 52 of the receptor layer 46 after the holes 54 have been formed, although this may not be required in all instances as will be discussed in more detail below in relation to FIGS. 3B and 3C.

The bonding layer 64 interfaces with the lower surface 52 of the receptor layer 46, and thereby “closes” one end of each hole 54 of the receptor layer 46. As will be discussed in more detail below, blocks 10 are positioned within the holes 54 through their respective remaining open end at the upper surface 50 of the receptor layer 46. Therefore, the bonding layer 64 may be characterized as being on one side of the receptor layer 46, and the blocks 10 may be characterized as being positioned in the holes 54 from the opposite side of the receptor layer 46.

The bonding material 68 of the bonding layer 64 may be of any appropriate type or composition, and further may be in any appropriate form. For instance, the bonding layer 64 may be a solid, liquid, or paste. When the bonding layer 64 is in the form of a liquid or paste, the bonding layer 64 should be sufficiently viscous. Using a solid (e.g., thermoplastics) as the bonding layer 64 may require a heat treatment to attain a desired degree of viscosity or a softening effect (using heat to soften or “liquify” the bonding layer 64, and such that the bonding layer 64 will return to its solid form when the heat treatment is terminated). Representative materials for the bonding layer 64 include without limitation epoxies, silicone adhesives, pressure-sensitive adhesives, and contact adhesives. A heat treatment of the bonding layer 64 may or may not be required.

The backup layer 74 is optional in at least certain cases. That is, the backup layer 74 may not be required in all instances. The backup layer 74 may be formed from any appropriate material or combination of materials. Furthermore, the backup layer 74 may be flexible, rigid, or otherwise. One function of the backup layer 74 may be to provide structural support for the substrate 42. Other functions may be provided by the backup layer 74 as well. For instance, the backup layer 74 may facilitate incorporating the bonding layer 64 into the structure of the substrate 42. The backup layer 74 may also function to constrain the bonding layer 64 in at least some manner. The backup layer 74 may also facilitate the “seating” of blocks 10 within the bonding layer 64 in a manner that will be discussed in more detail below.

Another embodiment of a multi-layered or composite substrate is illustrated in FIG. 3B and is identified by reference 76. Common components between the substrate 76 of FIG. 3B and the substrate 42 of FIG. 3A are identified by the same reference numeral, and the discussion presented above is equally applicable. A “single prime” designation is used to identify those corresponding components that differ in at least some respect. Initially, the backup layer 74 also is optional for the substrate 76, and thereby may not be used in all instances. The primary difference between the substrate 76 of FIG. 3B and the substrate 42 of FIG. 3A is that the bonding layer 64′ includes a plurality of holes 84 that are aligned with the holes 54 in the receptor layer 46. Typically this configuration would be the result of mounting or fixing the bonding layer 64′ on the lower surface 52 of the receptor layer 46 prior to the formation of its holes 54. The holes 84 in the bonding layer 64′ could then be formed simultaneously with the formation of the holes 54 in the receptor layer 46. That is, the holes 84 in the bonding layer 64 merely may be a remnant or artifact of the formation of the holes 54 in the receptor layer 46.

Yet another embodiment of a multi-layered or composite substrate is illustrated in FIG. 3C and is identified by reference 88. Common components between the substrate 88 of FIG. 3C and the substrate 42 of FIG. 3A are identified by the same reference normal, and the discussion presented above is equally applicable. Initially, the backup layer 74 also is optional for the substrate 88, and thereby may not be used in all instances. The primary difference between the substrate 88 of FIG. 3C and the substrate 42 of FIG. 3A is that instead of using a single bonding layer 64, the substrate 88 uses an upper bonding layer 64a and a lower bonding layer 64b. Both bonding layers 64a, 64b may be in accordance with the bonding layer 64 discussed above, except that the upper bonding layer 64a in the case of the substrate 88 includes a plurality of holes 96 that are aligned with the holes 54 in the receptor layer 46. Typically this configuration would be the result of mounting or fixing the upper bonding layer 64a on the lower surface 52 of the receptor layer 46 prior to the formation of its holes 54. The holes 96 in the upper bonding layer 64a could then be formed simultaneously with the formation of the holes 54 in the receptor layer 46. That is, the holes 96 in the upper bonding layer 64a may just be a remnant or artifact of the formation of the holes 54 in the receptor layer 46. Thereafter, the lower bonding layer 64b and the bIackup layer 74 may be properly positioned. For instance, the lower bonding layer 64b could be mounted on the backup layer 74, and then merged with the upper bonding layer 64a that is already fixed to the lower surface 52 of the receptor layer 46.

The bonding material 68 for each of the bonding layers 64, 64′ and 64a, 64b may be of any appropriate type as previously noted (e.g., adhesive impregnated carriers, such as cloth, mesh, paper). As will be discussed in more detail below, once blocks 10 are appropriately positioned within the holes 54 through the receptor layer 46, compression is used to dispose the upper surface 14 of each block 10 at least generally coplanar with the upper surface 50 of the receptor layer 46. In addition, bonding material 68 will “flow” into these holes 54 and preferably “fill” any gap between the block 10 within the hole 54 and the sidewall 56 that is disposed about the block 10.

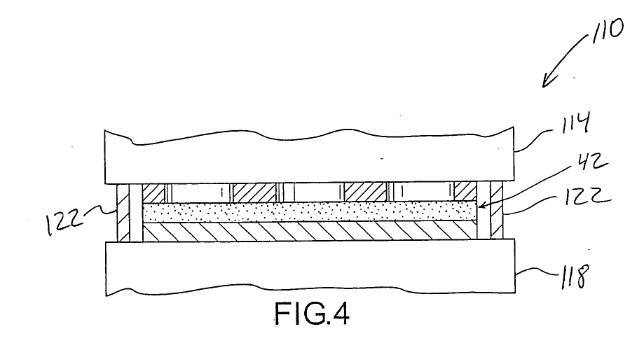

As noted above, the substrates 42, 76, and 88 may be assembled in any appropriate manner. FIG. 4 illustrates a representative example in relation to the substrate 42, but the same may be used for the substrates 76, 88 as well. An assembling apparatus 110 includes an upper fixture 114 and a lower fixture 118. The substrate 42 may be disposed between these fixtures 114 and 118 and at least slightly compressed, although such may not be required in all instances. That is, the upper fixture 114 and lower fixture 118 move relative to each other in any appropriate manner to increase or decrease the spacing therebetween. The amount of any compression of the substrate 42 may be limited by one or more by spacers 122 between the upper fixture 114 and lower fixture 118. The spacers 122 may not be required in all instances, and the compression pressure may be controlled in any appropriate manner. In one embodiment, the receptor layer 46, bonding layer 64, and backup layer 74 are separately formed. Thereafter, the bonding layer 64 is mounted on the backup layer 74. The receptor layer 46 is then appropriately positioned such that its lower surface 52 interfaces with the bonding layer 64, and the resulting stack is disposed between the upper fixture 114 and lower fixture 118 of the assembling apparatus 110. It may be necessary in at least certain cases to apply heat or otherwise control the temperature of the substrate 42 during the assembly thereof.

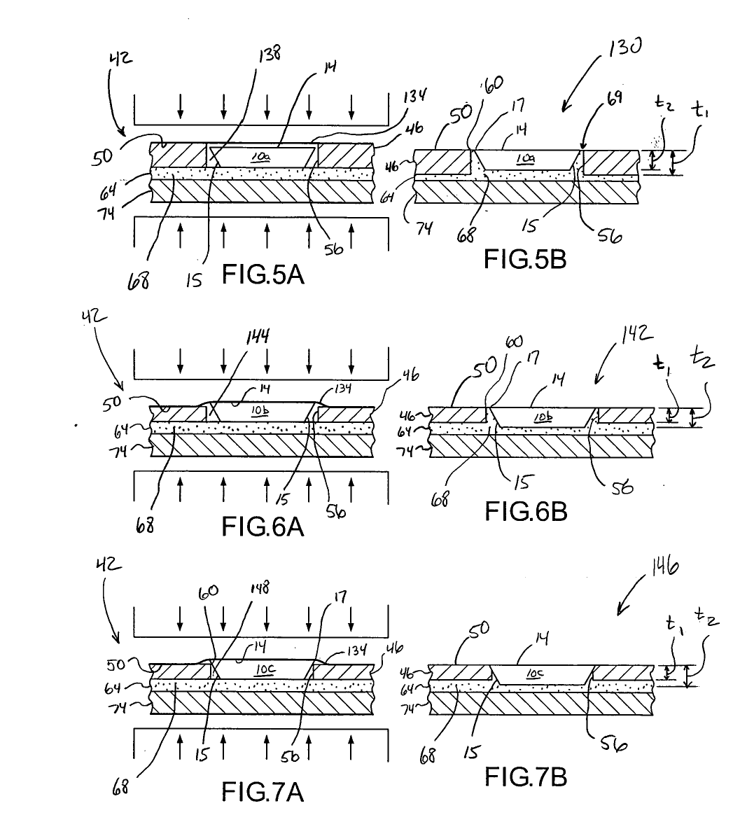

There are a number of implementations of the composite or multi-layered substrates 42, 76, and 88 in relation to how blocks 10 are integrated therewith to alleviate the need for a planarizing layer. FIGS. 5A-B, 6A-B, and 7A-B are three representative implementations (i.e., others may exist). Each of these “A” figures is a representative pre-compression configuration, while each of these “B” figures is a representative post-compression configuration. Although each of these implementations is illustrated in relation to the substrate 42 of FIG. 3A, they may also be used for the substrates 76 and 88 of FIGS. 3B and 3C, respectively. The same post-compression configurations illustrated in FIGS. 5B, 6B, and 7B thereby may be realized when using the substrates 76 and 88 as well.

Preferably, fluidic self assembly is used to dispose blocks 10 in the holes 54 of the substrate 42 for each of the above-noted implementations. However, any other appropriate technique for placing blocks 10 in the holes 54 could be utilized as well (e.g., pick and place). When fluidic self assembly is utilized, at least the receptor layer 46 of the substrate 42 is exposed to the fluid. It may be possible to use fluidic self assembly with just the receptor layer 42 (e.g., the bonding layer 64 could be incorporated after fluidic self assembly has taken place), with the bonding layer 64 already having been mounted to the receptor layer 42 and prior to mounting any backup layer 72, or with the entire substrate 42.

FIGS. 5A-B are directed to a substrate assembly 130. The substrate assembly 130 includes the substrate 42 and at least one block 10a. The block 10a is in accordance with the block 10 of FIG. 1 discussed above such that the corresponding portions thereof are identified by the same reference numeral. Each block 10a is disposed in its own hole 54 of the substrate 42.

There are a number of interrelationships of note between the substrate 42 and each of its blocks 10a in relation to the substrate assembly 130 of FIGS. 5A-B. One is that the thickness of the receptor layer 46 (t₁) is greater than the thickness of the block 10a (t₂). Therefore, at least part of the upper surface 14 of the block 10a may be recessed relative to the upper surface 50 of the receptor layer 46 after the block 10a is initially positioned within the hole 54. The entire lower surface 16 of the block 10a also may be disposed on the bonding layer 64 at this time. It should be appreciated that the upper surface 14 of the block 10a will not necessarily always be parallel to the upper surface 50 of the receptor layer 46 when the block 10a is initially positioned within the hole 54. That is, the block 10a could be “cocked” to a degree at this time (not shown).

Another interrelationship of note is that the block 10a may be disposed within a corresponding hole 54 without establishing a “zero clearance” fit between the block 10a and the receptor layer 46 (e.g., there may be a gap between at least a portion of the perimeter of the block 10a and the receptor layer 46 when the block 10a is disposed within the hole 54). Stated another way, the hole 54 is generally larger in at least some respect than the block 10a positioned therein. “Larger” is subject to a number of characterizations in relation to the illustrated embodiment. One is that the perimeter of each hole 54 at its upper edge 60 is larger any portion of the perimeter of the sidewall 15 of its corresponding block 10a. Another is that the “effective size” of the hole 54 at its upper edge 60 is larger than the maximum “effective size” of the sidewall 15 of the block 10a. Another is that the largest dimension of the hole 54 at its upper edge 60 is greater than the largest dimension of any portion of the sidewall 15 of the block 10a between the upper surface 14 of the block 10a and its lower surface 16. Yet another is that when the upper surface 14 of the block 10a is coplanar with the upper surface 50 of the receptor layer 46 (FIG. 5B), at least part of the upper edge 17 of the block 10a will be spaced from the upper edge 60 of its hole 54.

The “thickness dimension” of the substrate assembly 130 is compressed after the desired number of holes 54 of the receptor layer 46 have been “filled” with blocks 10a (e.g., compressed between its upper and lower extremes). Compression may be provided in any appropriate manner (e.g., using a pair of opposing planar supports; using a planar support and an opposing roller; using opposing rollers), and the compression pressure may be controlled in any appropriate manner. The entire substrate assembly 130 could be compressed all at once, or different portions could be separately compressed and including at the same or different times. In any case, it may be desirable to include an appropriate release film 134 that extends over the upper surface 50 of the receptor layer 46 and each of its holes 54 prior to compressing the substrate assembly 130. This release film 134 could be removed at any appropriate point after the substrate assembly 130 has been compressed in the desired manner. It may be necessary or at least desirable to heat or control the temperature of the substrate assembly 130 during compression. Any appropriate way of ensuring the release of the substrate assembly 130 from the compressing structure could be utilized (e.g., a release film on the compressing structure, alone or in combination with the release film 134; using an appropriate spray).

Compression of the substrate assembly 130 preferably disposes the upper surface 50 of the receptor layer 46 and the upper surface 14 of the block 10a in at least substantially coplanar relation as illustrated in FIG. 5B. Generally, bonding material 68 from the bonding layer 64 is forced or pushed into the hole 54 and in turn forces or pushes the block 10a toward the upper surface 50 of the receptor layer 46. That is, the position of the block 10a within the hole 54 is changed at least in some respect when the substrate assembly 130 is compressed. Compression of the substrate assembly 130 may also reduce the thickness of one or more portions of the bonding layer 64 that are not aligned with a hole 54 through the receptor layer 46. It may be possible that the compression of the substrate assembly 130 will actually dispose the backup layer 74 against the lower surface 52 of the receptor layer 46, although preferably at least a portion of the bonding layer 64 will remain between the receptor layer 46 and the backup layer 74.

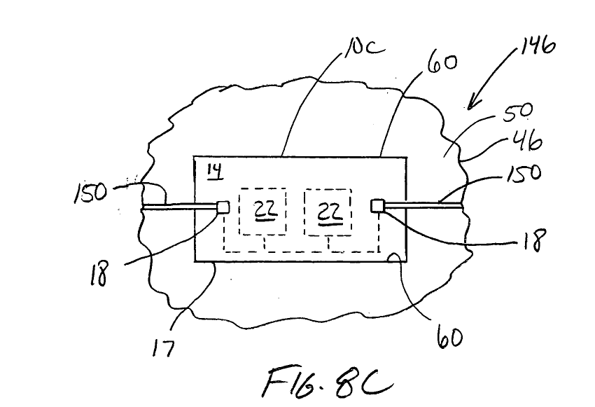

After the upper surface 14 of each block 10a has been disposed in at least substantially coplanar relation with the upper surface 50 of the receptor layer 46 (FIG. 5B), at least part of the upper edge 17 of the block 10a will be spaced from the receptor layer 46 in the case of the substrate assembly 130. This thereby encompasses having the entire upper edge 17 of the block 10a be spaced from the receptor layer 46 (more specifically the sidewall 56 that defines the hole 54) as in the case of the FIG. 5B configuration. In this case the bonding material 68 from the bonding layer 64 is disposed about the entire perimeter of the upper edge 17 of the block 10a (e.g., for the case where the block 10a is “centered” in the hole 54). However, this also encompasses having one part of the upper edge 17 of the block 10a being spaced from the receptor layer 46 (again, more specifically the sidewall 56 that defines the hole 54), and having another part of the upper edge 17 of the block 10a physically contacting the receptor layer 46 (e.g., the block 10a may be “off center” within the hole 54, such as illustrated in FIG. 8B that is discussed below).

Finally, preferably any gap between the receptor layer 46 and the block 10a within the hole 54 is occupied by bonding material 68 after the substrate assembly 130 has been compressed. Compare FIGS. 5A and 5B. In FIG. 5A, an open space 138 exists between the receptor layer 46 (more specifically the sidewall 56 of the hole 54) and at least part of the sidewall 15 of the block 10a before the substrate assembly 130 has been compressed. In FIG. 5B, this open space 138 has been replaced by bonding material 68 that has been forced into the hole 54 by compression of the substrate assembly 130. The upper end 69 of the bonding material 68 within each hole 54 preferably will be at least substantially coplanar with both the upper surface 50 of the receptor layer 46 and the upper surface 14 of the block 10a after the compression. This provides a suitable surface across which an electrical interconnect may extend and that appropriately supports the electrical interconnect.

Some type of heat treatment may be required prior to, during, and/or after the compression has been completed in accordance with the foregoing. Heat treatment may not be required in all instances. In any case, the bonding material 68 will fix the block 10a within the hole 54 (e.g., such that there is no relative movement therebetween). Furthermore, the upper end 69 of the bonding material 68 will provide a suitable surface for supporting any electrical interconnect that extends across this upper end 69 to reach the upper surface 14 of the block 10a.

FIGS. 6A-B are directed to a substrate assembly 142. The substrate assembly 142 includes the substrate 42 and at least one block 10b. The block 10b is in accordance with the block 10 of FIG. 1 discussed above such that the corresponding portions thereof are identified by the same reference numeral. Each block 10b is disposed in its own hole 54 of the substrate 42.

There are a number of interrelationships of note between the substrate 42 and each of its blocks 10b in relation to the substrate assembly 142 of FIGS. 6A-B. One is that the thickness of the receptor layer 48 (t₁) is less than the thickness of the block 10b (t₂). Therefore, at least part of the upper surface 50 of the receptor layer 46 may be recessed from the upper surface 14 of the block 10b. Stated another way, the block 10b may protrude beyond the upper surface 50 of the receptor layer 46 when initially positioned with the hole 54. The entire lower surface 16 of the block 10b also may be disposed on the bonding layer 64 at this time. It should be appreciated that the upper surface 14 of the block 10b will not necessarily always be parallel to the upper surface 50 of the receptor layer 46 when the block 10b is initially positioned within the hole 54. That is, the block 10b could be “cocked” to a degree at this time (not shown).

Another interrelationship of note is that the block 10b may be disposed within a corresponding hole 54 without establishing a zero clearance fit between the block 10b and the receptor layer 46. Stated another way, the hole 54 is generally larger in at least some respect than the block 10b to be positioned therein. “Larger” is subject to a number of characterizations in relation to the illustrated embodiment. One is that the perimeter of each hole 54 at its upper edge 60 is larger than any portion of the perimeter of the sidewall 15 of its corresponding block 10b. Another is that the “effective size” of the hole 54 at its upper edge 60 is larger than the maximum “effective size” of the sidewall 15 of the block 10b. Another is that the largest dimension of the hole 54 at its upper edge 60 is greater than the largest dimension of any portion of the sidewall 15 of the block 10b. Yet another is that when the upper surface 14 of the block 10b is coplanar with the upper surface 50 of the receptor layer 46 (FIG. 6B), at least part of the upper edge 17 of the block 10b will be spaced from the upper edge 60 of its hole 54.

The “thickness dimension” of the substrate assembly 142 is compressed after the desired number of holes 54 of the receptor layer 46 have been “filled” with blocks 10b (e.g., compressed between its upper and lower extremes). Compression may be provided in any appropriate manner (e.g., using a pair of opposing planar supports; using a planar support and an opposing roller; using opposing rollers), and the compression pressure may be controlled in any appropriate manner. The entire substrate assembly 142 could be compressed all at once, or different portions could be separately compressed and including at the same or different times. In any case, it may be desirable to include an appropriate release film 134 that extends over the upper surface 50 of the receptor layer 46 and each of its holes 54 prior to compressing the substrate assembly 142. This release film 134 could be removed at any appropriate point after the substrate assembly 142 has been compressed in the desired manner. It may be necessary or at least desirable to heat or control the temperature of the substrate assembly 142 during compression. Any appropriate way of ensuring the release of the substrate assembly 142 from the compressing structure could be utilized (e.g., a release film on the compressing structure, alone or in combination with the release film 134; using an appropriate spray).

Compression of the substrate assembly 142 preferably disposes the upper surface 50 of the receptor layer 46 and the upper surface 14 of the block 10b in at least substantially coplanar relation as illustrated in FIG. 6B. Generally, the block 10b is forced down or seated into the bonding layer 64. In addition, bonding material 68 from the bonding layer 64 is forced or pushed into the hole 54. In any case, the position of the block 10b within the hole 54 is changed at least in some respect when the substrate assembly 142 is compressed. Bonding material 68 preferably remains between the lower surface 16 of the block 10b and the backup layer 74 as shown. Alternatively, the lower surface 16 of the block 10b could end up coplanar with the lower surface of the bonding layer 64 or may in fact be disposed beyond the lower surface of the bonding layer 64 (e.g., such that the lower surface 16 protrudes completely through the bonding layer 64).

After the upper surface 14 of each block 10b has been disposed in at least substantially coplanar relation with the upper surface 50 of the receptor layer 46 (FIG. 6B), at least part of the upper edge 17 of the block 10b will be spaced from the receptor layer 46. This thereby encompasses having the entire upper edge 17 of the block 10b be spaced from the receptor layer 46 (more specifically the sidewall 56 that defines the hole 54) as in the case of the FIG. 6B configuration. In this case the bonding material 68 from the bonding layer 64 is disposed about the entire perimeter of the upper edge 17 of the block 10b (e.g., for the case where the block 10b is “centered” in the hole 54). However, this also encompasses having one part of the upper edge 17 of the block 10b being spaced from the receptor layer 46 (again, more specifically the sidewall 56 that defines the hole 54), and having another part of the upper edge 17 of the block 10b physically contacting the receptor layer 46 (e.g., the block 10b may be “off center” within the hole 54, such as illustrated in FIG. 8B that is discussed below).

Finally, preferably any gap between the receptor layer 46 and the block 10b within the hole 54 is occupied by bonding material 68 after the substrate assembly 142 has been compressed. Compare FIGS. 6A and 6B. In FIG. 6A, an open space 144 exists between the receptor layer 46 (more specifically the sidewall 56 of the hole 54) and at least part of the sidewall 15 of the block 10b before the substrate assembly 142 has been compressed. In FIG. 6B, this open space 144 has been replaced by bonding material 68 that has been forced into the hole 54 by compression of the substrate assembly 142. The upper end 69 of the bonding material 68 within each hole 54 preferably will be at least substantially coplanar with both the upper surface 50 of the receptor layer 46 and the upper surface 14 of the block 10b after the compression. This provides a suitable surface across which an electrical interconnect may extend and that appropriately supports the electrical interconnect.

Some type of heat treatment may be required prior to, during, and/or after the compression has been completed in accordance with the foregoing. Heat treatment may not be required in all instances. In any case, the bonding material 68 will fix the block 10b within the hole 54 (e.g., such that there is no relative movement therebetween). Furthermore, the upper end 69 of the bonding material 68 will provide a suitable surface for supporting any electrical interconnect that extends across the upper end 69 to reach the upper surface 14 of the block 10b.

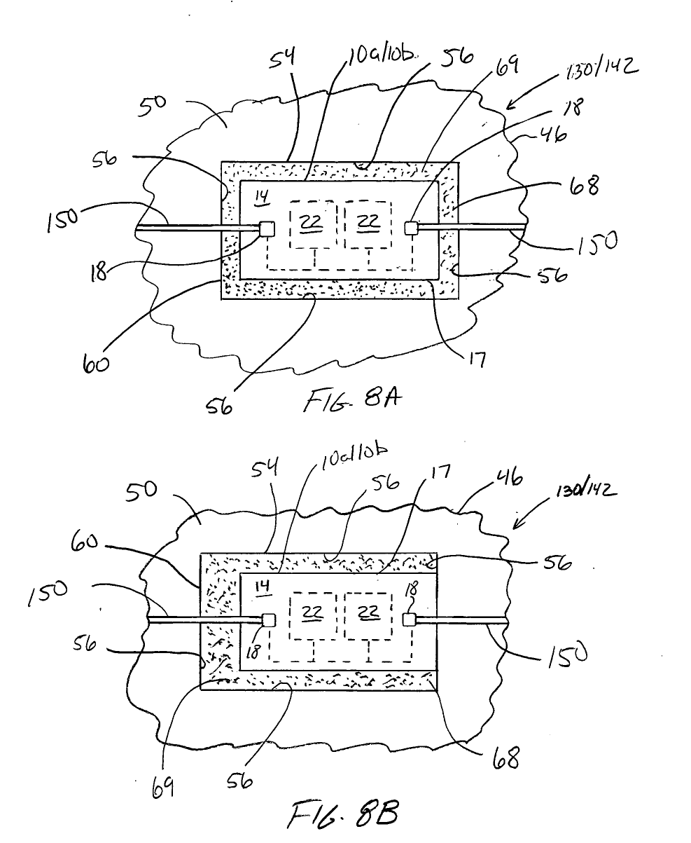

FIGS. 7A-B are directed to a substrate assembly 146. The substrate assembly 146 includes the substrate 42 and at least one block 10c. The block 10c is in accordance with the block 10 of FIG. 1 discussed above such that the corresponding portions thereof are identified by the same reference numeral. Each block 10c is disposed in its own hole 54 of the substrate 42.

There are a number of interrelationships of note between the substrate 42 and each of its blocks 10c in relation to the substrate assembly 146 of FIGS. 7A-B. One is that the thickness of the receptor layer 46 (t₁) is less than the thickness of the block 1c (t₂). Therefore, at least part of the upper surface 50 of the receptor layer 46 may be recessed from the upper surface 14 of the block 10c. Stated another way, the block 10c may protrude beyond the upper surface 50 of the receptor layer 46 when initially positioned with the hole 54. The entire lower surface 16 of the block 10c also may be disposed on the bonding layer 64 at this time. It should be appreciated that the upper surface 14 of the block 10c will not necessarily always be parallel to the upper surface 50 of the receptor layer 46 when the block 10c is initially positioned within the hole 54. That is, the block 10c could be “cocked” to a degree at this time (not shown).

Another interrelationship of note is that the block 10c is disposed within a corresponding hole 54 by establishing a zero clearance fit between the block 10c and the receptor layer 46. Stated another way, the hole 54 is generally smaller in at least some respect than the block 10c to be positioned therein. “Smaller” is subject to a number of characterizations in relation to the illustrated embodiment. One is that the perimeter of each hole 54 at its upper edge 60 is smaller than the perimeter of at least part of the sidewall 15 of its corresponding block 10c. Another is that the “effective size” of the hole 54 at its upper edge 60 is smaller than the maximum “effective size” of the sidewall 15 of the block 10c. Another is that the largest dimension of the hole 54 at its upper edge 60 is smaller than the largest dimension of at least part of the sidewall 15 of the block 10c. Yet another is that when the upper surface 14 of the block 10c is coplanar with the upper surface 50 of the receptor layer 46 (FIG. 7B), the entire upper edge 17 of the block 10c will be contacting the receptor layer 46 (at or close to the upper edge 60 of the hole 54).

The “thickness dimension” of the substrate assembly and 46 is compressed after the desired number of holes 54 of the receptor layer 46 have been “filled” with blocks 10c (e.g., compressed between its upper and lower extremes). Compression may be provided in any appropriate manner (e.g., using a pair of opposing planar supports; using a planar support and an opposing roller; using opposing rollers), and the compression pressure may be controlled in any appropriate manner. The entire substrate assembly 146 could be compressed all at once, or different portions could be separately compressed and including at the same or different times. In any case, it may be desirable to include an appropriate release film 134 that extends over the upper surface 50 of the receptor layer 46 and each of its holes 54 prior to compressing the substrate assembly 146. This release film 134 could be removed at any appropriate point after the substrate assembly 146 has been compressed in the desired manner. It may be necessary or at least desirable to heat or control the temperature of the substrate assembly 146 during compression. Any appropriate way of ensuring the release of the substrate assembly 46 from the compressing structure could be utilized (e.g., a release film on the compressing structure, alone or in combination with the release film 134; using an appropriate spray).

Compression of the substrate assembly 146 preferably disposes the upper surface 50 of the receptor layer 46 and the upper surface 14 of the block 10c in at least substantially coplanar relation as illustrated in FIG. 7B. Generally, the block 10c is forced down or seated into the bonding layer 64. In addition, bonding material 68 from the bonding layer 64 is forced or pushed into the hole 54. In any case, the position of the block 10c within the hole 54 is changed at least in some respect when the substrate assembly 146 is compressed. Bonding material 68 preferably remains between the lower surface 16 of the block 10c and the backup layer 74. Alternatively, the lower surface 16 of the block 10c could end up coplanar with the lower surface of the bonding layer 64 or may in fact be disposed beyond the lower surface of the bonding layer 64 (e.g., such that the lower surface 16 protrudes completely through the bonding layer 64).

Contact between the block 10c and the sidewall 56 of the hole 54 during compression of the substrate assembly 146 also expands at least a portion of the hole 56 to provide the noted zero clearance fit between the block 10c and the receptor layer 46. In the illustrated embodiment, an upper, annular portion of the sidewall 56 associated with the hole 54 may be at least slightly deformed by the compression of the substrate assembly 146 and the resulting engagement between the sidewall 15 of the block 10c and the sidewall 56. When the upper surface 50 of the receptor layer 46 and the upper surface 14 of the block 10c are disposed in coplanar relation, there should not be any gap of any significance between the upper edge 60 of the hole 54 and the upper edge 17 of the block 10c positioned within the hole 54. This provides a suitable surface across which an electrical interconnect may extend and that appropriately supports the electrical interconnect. It should be appreciated that the block 10c and the hole 54 could be the same size and realize a zero clearance fit as well (where disposing the upper surface 50 of the receptor layer 46 at least substantially coplanar with the upper surface 14 of the block 10c does not deform either the receptor layer 46 or the block 10c).

Finally, preferably any gap between the receptor layer 46 and the block 10b within the hole 54 is occupied by bonding material 68 after the substrate assembly 146 has been compressed. Compare FIGS. 7A and 7B. In FIG. 7A, an open space 148 exists between the receptor layer 46 (more specifically the sidewall 56 of the hole 54) and at least part of the sidewall 15 of the block 10c before the substrate assembly 146 has been compressed. In FIG. 7B, this open space 148 has been replaced by bonding material 68 that has been forced into the hole 54 by compression of the substrate assembly 146.

The representative implementations of FIGS. 5A-B, 6A-B, and 7A-B alleviate the need for a planarizing layer and yet provide a desired surface on which one or more electrical interconnects may be disposed. These electrical interconnects may be of any appropriate type, size, shape, and configuration (e.g., a line, a trace). FIGS. 8A and 8B are representative end configurations from the implementations of FIGS. 5A-B and 6A-B, and are applicable to the substrates 42 (FIG. 3A), 76 (FIG. 3B), and 88 (FIG. 3C). FIG. 8A illustrates the case where the entire block 10a/10b remains spaced from the receptor layer 46 after the compression such that the upper end 69 of the bonding material 68 within the hole 54 extends about the entire perimeter of the block 10a/10b. This of course may be realized with the block 10a/10b being centered within the hole 54, or with the block 10a/10b being off-center to a degree within the hole 54. In any case, here the upper surface 14 of the block 10a/10b, the upper surface 50 of the receptor layer 46, and the upper end 69 of the bonding material 68 within the hole 54 are at least substantially coplanar. An electrical interconnect 150 may then extend across the upper surface 50 of the receptor layer 46, the upper end 69 of the bonding material 68 within the hole 54, and onto the upper surface 14 of the block 10a/10b. The entirety of the electrical interconnect 150 is thereby directly supported.

FIG. 8B illustrates one case where part of the block 10a/10b contacts the receptor layer 46 after the compression, and where the remainder of the block 10a/10b is separated from the receptor layer 46. However, this space is occupied by bonding material 68. Various other arrangements of this general type are possible. However, for all cases of this type the upper surface 14 of the block 10a/10b, the upper surface 50 of the receptor layer 46, and the upper end 69 of the bonding material 68 within the hole 54 are at least substantially coplanar. An electrical interconnect 150 may then extend across the upper surface 50 of the receptor layer 46, the upper end 69 of the bonding material 68 within the hole 54, and onto the upper surface 14 of the block 10a/10b. The entirety of the electrical interconnect 150 is thereby directly supported.

FIG. 8C is a representative end configuration from the implementation of FIGS. 7A-B, and is applicable to the substrates 42 (FIG. 3A), 76 (FIG. 3B), and 88 (FIG. 3C). Again, the upper surface 14 of the block 10a/10b and the upper surface 50 of the receptor layer 46, are at least substantially coplanar. An electrical interconnect 150 may then extend across the upper surface 50 of the receptor layer 46 and directly onto the upper surface 14 of the block 10c by the press fit between the block 10c and receptor layer 46 at its upper surface 50.

The foregoing description of the present invention has been presented for purposes of illustration and description. Furthermore, the description is not intended to limit the invention to the form disclosed herein. Consequently, variations and modifications commensurate with the above teachings, and skill and knowledge of the relevant art, are within the scope of the present invention. The embodiments described hereinabove are further intended to explain best modes known of practicing the invention and to enable others skilled in the art to utilize the invention in such, or other embodiments and with various modifications required by the particular application(s) or use(s) of the present invention. It is intended that the appended claims be construed to include alternative embodiments to the extent permitted by the prior art.

What is claimed is:

1. A substrate assembly, comprising:
a receptor layer comprising first and second surfaces that are oppositely disposed, wherein a first hole extends between said first and second surfaces;
a first block disposed within said first hole in said receptor layer, wherein said first block comprises a first electrical terminal;
a bonding material that interfaces with said second surface of said receptor layer; and
a first electrical interconnect that extends along said first surface of said receptor layer and to said first electrical terminal of said first block.

2. A substrate assembly, as claimed in claim 1, wherein:
said receptor layer is a dielectric material.

3. A substrate assembly, as claimed in claim 1, wherein:
said first electrical terminal is on a first surface of said first block.

4. A substrate assembly, as claimed in claim 3, wherein:
said first surface of said first block is at least substantially coplanar with said first surface of said receptor layer.

5. A substrate assembly, as claimed in claim 3, wherein:
said first block comprises a second surface that is opposite said first surface, and wherein said first block is seated within said bonding material such that an entirety of said second surface of said first block is in contact said bonding material.

6. A substrate assembly, as claimed in claim 1, wherein:
said first block comprises first and second surfaces that are oppositely disposed and an annular sidewall that extends between said first and second surfaces, wherein said first surface of said first block is at least substantially coplanar with said first surface of said receptor layer, and wherein at least part of said sidewall of said first block is spaced from a first sidewall of said receptor layer that defines a perimeter of said first hole.

7. A substrate assembly, as claimed in claim 1, wherein:
said receptor layer comprises an annular sidewall that defines said first hole, wherein said first block is separated from said annular sidewall by a first annular space, and wherein said bonding material at least substantially occupies said first annular space.

8. A substrate assembly, as claimed in claim 1, wherein:
any gap between said receptor layer and said first block is occupied by said bonding material.

9. A substrate assembly, as claimed in claim 1, wherein:
said first block comprises an annular sidewall, wherein said receptor layer comprises an annular first sidewall that defines a perimeter of said first hole, wherein an annular first portion of said sidewall of said first block is in contact with said first sidewall of said receptor layer, wherein a remainder of said sidewall of said first block is separated from said first sidewall of receptor layer by a first space, and wherein said first space is at least substantially occupied by said bonding material.

10. A substrate assembly, as claimed in claim 9, wherein:
there is a zero clearance fit between said receptor layer and said annular first portion of said first block.

11. A substrate assembly, as claimed in claim 1, wherein:
said annular first portion of said sidewall of said first block is an uppermost portion of said sidewall of said first block.

12. A substrate assembly, as claimed in claim 1, wherein:
said bonding material comprises an adhesive impregnated carrier.

13. A substrate assembly, as claimed in claim 1, further comprising:
a backup layer, wherein said bonding material is disposed between said backup layer and said receptor layer.

14. A substrate assembly, as claimed in claim 1, further comprising:
a release film disposed on said first surface of said receptor layer and on said first block.

15. A method for making a substrate assembly using a receptor layer comprising first and second sides that are oppositely disposed, said method comprising the steps of:
directing a first block within a first hole in said receptor layer from said first side of said receptor layer, wherein said first block comprises a first electrical terminal, and wherein said first hole extends from said first side of said receptor layer to said second side of said receptor layer;
disposing a bonding layer on said second side of said receptor layer, wherein a substrate comprises said receptor layer and said bonding layer;
compressing said substrate after said directing a first block step and said disposing step have been executed; and
directing a bonding material from said bonding layer into a space between said first block and an annular first sidewall of said receptor layer that defines a perimeter of said first hole.

16. A method, as claimed in claim 15, wherein:
said directing a first block step comprises using fluidic self assembly.

17. A method, as claimed in claim 15, wherein:
said directing a first block step comprises disposing said first block within a fluid and establishing contact between said fluid and said first side of said receptor layer.

18. A method, as claimed in claim 15, wherein:
said directing a first block step comprises:
disposing a plurality of blocks into a fluid to form a slurry, wherein said first block is one of said plurality of blocks, and wherein said first hole and each of said plurality of blocks are complimentarily shaped; and
exposing at least said first side of said receptor layer to said slurry.

19. A method, as claimed in claim 15, wherein:
said directing a first block step is executed before said disposing a bonding layer step.

20. A method, as claimed in claim 15, wherein:
said directing a first block step is executed after said disposing a bonding layer step.

21. A method, as claimed in claim 15, wherein:
said receptor layer is of a first thickness, wherein said first block is of a second thickness that is less than said first thickness such that a first surface of said first block is recessed relative to a first surface of said receptor layer on said first side prior to said compressing step, and wherein said compressing step comprises disposing said first surface of said receptor layer on said first side at least substantially coplanar with said first surface of said first block.

22. A method as claimed in claim 21, wherein:
said first surface of said first block comprises a first electrical terminal, wherein said method further comprises the step of forming a first electrical interconnect that is disposed on both said first surface of said receptor layer and on said first surface of said first block so as to contact to said first electrical terminal.

23. A method, as claimed in claim 21, wherein:
said first block comprises a second surface that is opposite said first surface of said first block, as well as an annular sidewall that extends between said first and second surfaces of said first block, wherein an intersection of said sidewall with said first surface of said first block defines an edge, wherein a first part of said edge of said first block is in contact with said first sidewall of said receptor layer and a remainder of said edge is spaced from said first sidewall of said receptor layer, and wherein an entirety of a gap between said first sidewall of said receptor layer and said sidewall of said first block within said first hole is occupied by said bonding material from said directing a bonding material step.

24. A method, as claimed in claim 21, wherein:
said first block comprises a second surface that is opposite said first surface of said first block, as well as an annular sidewall that extends between said first and second surfaces of said first block, wherein an intersection of said sidewall with said first surface of said first block defines an edge, wherein an entirety of both said edge and said sidewall of said first block are spaced inwardly from said first sidewall of said receptor layer, wherein an entirety of a gap between said first sidewall of said receptor layer and said sidewall of said first block within said first hole is occupied by said bonding material from said directing a bonding material step.

25. A method, as claimed in claim 15, wherein:
said receptor layer is of a first thickness, wherein said first block is of a second thickness that is greater than said first thickness such that a first surface of said receptor layer on said first side is recessed relative to a first surface of said first block prior to said compressing step, and wherein said compressing step comprises disposing said first surface of said receptor layer on said first side at least substantially coplanar with said first surface of said first block.

26. A method as claimed in claim 25, wherein:
said first surface of said first block comprises a first electrical terminal, wherein said method further comprises the step of forming a first electrical interconnect that is disposed on both said first surface of said receptor layer and on said first surface of said first block so as to contact said first electrical terminal.

27. A method, as claimed in claim 25, wherein:
said first block comprises a second surface that is opposite said first surface of said first block, as well as an annular sidewall that extends between said first and second surfaces of said first block, wherein an intersection of said sidewall with said first surface of said first block defines an edge, wherein a first part of said edge of said first block is in contact with said first sidewall of said receptor layer and a remainder of said edge is spaced from said first sidewall of said receptor layer, and wherein an entirety of a gap between said first sidewall of said receptor layer and said sidewall of said first block within said first hole is occupied by said bonding material from said directing a bonding material step.

28. A method, as claimed in claim 25, wherein:
said first block comprises a second surface that is opposite said first surface of said first block, as well as an annular sidewall that extends between said first and second surfaces of said first block, wherein an intersection of said sidewall with said first surface of said first block defines an edge, wherein an entirety of both said edge and said sidewall of said first block are spaced inwardly from said first sidewall of said receptor layer, wherein an entirety of a gap between said first sidewall of said receptor layer and said sidewall of said first block within said first hole is occupied by said bonding material from said directing a bonding material step.

29. A method, as claimed in claim 25, wherein:
an annular first portion of said first block contacts said first sidewall of said receptor layer before said compressing step, wherein an annular second portion of said first block is separated from said first sidewall of said receptor layer by a first space both before and after said compressing step, wherein said second portion is located in a direction of said bonding layer from said first portion, and wherein at least substantially all of said first space is occupied by said bonding material from said directing a bonding material step.

30. A method, as claimed in claim 25, wherein:
said compressing step comprises creating a zero clearance fit between said first sidewall of said receptor layer and an upper portion of said first block, wherein an entirety of a lower portion of said first block is separated from said first sidewall by a first space both before and after said compressing step, and wherein at least substantially all of said first space is occupied by said bonding material from said directing a bonding material step.

31. A method, as claimed in claim 25, wherein:
said compressing step comprises enlarging an annular first portion of said first sidewall of said receptor layer through contact with a perimeter of said first block, wherein a remainder of said first sidewall remains separated from said perimeter of said first block by a first space, and wherein at least substantially all of said first space is occupied by said bonding material from said directing a bonding material step.

32. A method, as claimed in claim 15, wherein:
said bonding layer comprises a plurality of hollow objects, wherein each of said hollow objects contains an adhesive, and wherein said compressing step bursts at least some of said hollow objects.

33. A method, as claimed in claim 15, further comprising the steps of:
disposing a release layer over said receptor layer and said first block after said directing a first block step and before said compressing step; and
removing said release layer after said compressing and directing a bonding material steps.

34. A method, as claimed in claim 15, further comprising the step of:
locating said bonding layer between said receptor layer and a backup layer before said compressing step.

35. A method, as claimed in claim 15, further comprising the step of forming a first electrical interconnect that extends along a first surface of said receptor layer and onto a first surface of said first block after said compressing and directing a bonding material steps, wherein said compressing step comprises disposing said first surface of said receptor layer at least substantially coplanar with said first surface of said first block.

36. A method for making a substrate assembly using a receptor layer comprising first and second surfaces that are oppositely disposed, wherein said receptor layer further comprises a first hole that extends from said first surface to said second surface of said receptor layer, said method comprising the steps of:
positioning a first block within said first hole, wherein said first block comprises a first electrical terminal on a first surface of said first block;
disposing a bonding layer on said second surface of said receptor layer, wherein a substrate comprises said receptor layer and said bonding layer;
compressing said substrate;
disposing said first surface of said first block at least substantially coplanar with, said first surface of said receptor layer; and
forming a first electrical interconnect that extends along said first surface of said receptor layer and onto said first surface of said first block.

37. A method, as claimed in claim 36, wherein:
said positioning step comprises using fluidic self assembly.

38. A method, as claimed in claim 36, wherein:
said positioning step comprises disposing said first block within a fluid and establishing contact between said fluid and said first surface of said receptor layer.

39. A method, as claimed in claim 36, wherein:
said positioning step comprises:
disposing a plurality of blocks into a fluid to form a slurry, wherein said first block is one of said plurality of blocks, and wherein said first hole and each of said plurality of blocks are complimentarily shaped; and
exposing said first surface of said receptor layer to said slurry.

40. A method, as claimed in claim 36, wherein:
said positioning step is executed before said disposing a bonding layer step.

41. A method, as claimed in claim 36, wherein:
said positioning step is executed after said disposing a bonding layer step.

42. A method, as claimed in claim 36, wherein:
said receptor layer is of a first thickness, wherein said first block is of a second thickness that is less than said first thickness such that said first surface of said first block is recessed relative to said first surface of said receptor layer prior to said compressing step, and wherein said compressing step comprises directing a bonding material from said bonding layer into a space between a first sidewall of said receptor layer that defines said first hole and said first block within said first hole.

43. A method as claimed in claim 42, wherein:
said first surface of said first block comprises a first electrical terminal, wherein said forming step is executed such that said first electrical interconnect extends to said first electrical terminal.

44. A method, as claimed in claim 42, wherein:
said first block comprises a second surface that is opposite said first surface of said first block, as well as an annular sidewall that extends between said first and second surfaces of said first block, wherein an intersection of said sidewall with said first surface of said first block defines an edge, wherein a first part of said edge of said first block is in contact with said first sidewall of said receptor layer and a remainder of said edge is spaced from said first sidewall of said receptor layer, and wherein an entirety of a gap between said first sidewall of said receptor layer and said sidewall of said first block within said first hole is occupied by said bonding material from said directing a bonding material step.

45. A method, as claimed in claim 42, wherein:
said first block comprises a second surface that is opposite said first surface of said first block, as well as an annular sidewall that extends between said first and second surfaces of said first block, wherein an intersection of said sidewall with said first surface of said first block defines an edge, wherein an entirety of both said edge and said sidewall of said first block are spaced inwardly from said first sidewall of said receptor layer, wherein an entirety of a gap between said first sidewall of said receptor layer and said sidewall of said first block within said first hole is occupied by said bonding material from said directing a bonding material step.

46. A method, as claimed in claim 36, wherein:
said receptor layer is of a first thickness, wherein said first block is of a second thickness that is greater than said first thickness such that said first surface of said receptor layer is recessed relative to said first surface of said first block prior to said compressing step, and wherein said compressing step comprises directing a bonding material from said bonding layer into a space between a first sidewall of said receptor layer that defines said first hole and said first block within said first hole.

47. A method as claimed in claim 46, wherein:
said first surface of said first block comprises a first electrical terminal, wherein said forming step is executed such that said first electrical interconnect extends to said first electrical terminal.

48. A method, as claimed in claim 46, wherein:
said first block comprises a second surface that is opposite said first surface of said first block, as well as an annular sidewall that extends between said first and second surfaces of said first block, wherein an intersection of said sidewall with said first surface of said first block defines an edge, wherein a first part of said edge of said first block is in contact with said first sidewall of said receptor layer and a remainder of said edge is spaced from said first sidewall of said receptor layer, and wherein an entirety of a gap between said first sidewall of said receptor layer and said sidewall of said first block within said first hole is occupied by said bonding material from said directing a bonding step.

49. A method, as claimed in claim 46, wherein:
said first block comprises a second surface that is opposite said first surface of said first block, as well as an annular sidewall that extends between said first and second surfaces of said first block, wherein an intersection of said sidewall with said first surface of said first block defines an edge, wherein an entirety of both said edge and said sidewall of said first block are spaced inwardly from said first sidewall of said receptor layer, wherein an entirety of a gap between said first sidewall of said receptor layer and said sidewall of said first block within said first hole is occupied by said bonding material from said directing a bonding material step.

50. A method, as claimed in claim 46, wherein:
an annular first perimeter portion of said first block contacts said first sidewall of said receptor layer before said compressing step, wherein an annular second portion of said first block is separated from said first sidewall of said receptor layer by a first space both before and after said compressing step, wherein said second portion is located in a direction of said bonding layer from said first portion, and wherein at least substantially all of said first space is occupied by said bonding material from said directing a bonding material step.

51. A method, as claimed in claim 46, wherein:
said compressing step comprises creating a zero clearance fit between said first sidewall of said receptor layer and an upper portion of said first block, wherein an entirety of a lower portion of said first block is separated from said first sidewall by a first space both before and after said compressing step, and wherein at least substantially all of said first space is occupied by said bonding material from said directing a bonding material step.

52. A method, as claimed in claim 46, wherein:
said compressing step comprises enlarging an annular first portion of said first sidewall of said receptor layer through contact with a perimeter of said first block, wherein a remainder of said first sidewall remains separated from said perimeter of said first block by a first space, and wherein at least substantially all of said first space is occupied by said bonding material from said directing a bonding material step.

53. A method, as claimed in claim 36, wherein:
said bonding layer comprises a plurality of hollow objects, wherein each of said hollow objects contains an adhesive, and wherein said compressing step bursts at least some of said hollow objects.

54. A method, as claimed in claim 36, further comprising the steps of:
disposing a release layer over said receptor layer and said first block after said positioning step and before said compressing step; and
removing said release layer after said compressing and disposing said first surface steps.

55. A method, as claimed in claim 36, further comprising the step of:
locating said bonding layer between said receptor layer and a backup layer before said compressing step.
